(19) United States
(12) Patent Application Publication
(10) Pub. No.: US 2005/0133853 A1
(43) Pub. Date: Jun. 23, 2005

(54) Flash memory cell and method of erasing the same

(76) Inventor: Hee Youl Lee, Kyungki-Do (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 10/881,423

(22) Filed: Jun. 30, 2004

(30) Foreign Application Priority Data
Dec. 22, 2003 (KR) 2003-94453

(51) Int. Cl. G11C 11/34

(52) U.S. Cl. 257/315

(57) ABSTRACT

Provided is related to a flash memory cell and method of erasing the same. A P-type well field-effective flash cell is comprised of a drain formed in a P-type semiconductor substrate, a channel region made of a triple N-well, a source of P-well formed in the triple N-well, a floating gate formed on the channel region, a tunnel oxide film formed under the floating gate, a control gate formed with a predetermined pattern on the overall structure including the floating gate, and a dielectric film formed under the control gate. When the flash cell is turned on at a predetermined threshold voltage to drop a P-well bias, an electric field between the floating gate and the semiconductor substrate weakens to inhibit electron injection that is caused by F-N tunneling effect and thereby an erased threshold voltage goes to a target voltage.

### BACKGROUND

1. Field of the Invention

The present invention relates to a flash memory cell and method of erasing the same, and particularly to a flash memory cell and method of erasing the same, by which a characteristic of erasing can be enhanced.

2. Discussion of Related Art

In general, a flash memory cell is constituted of a tunnel oxide film, a floating gate, a dielectric film, a control gate, and a source/drain, in which its threshold voltage varies depending on the amount of electrons trapped at the floating gate by an operation of programming or erasing. During a read operation, the amount of a drain current flowing through the cell varies in accordance with its threshold voltage, which determines data of the flash memory cell as “1” or “0”.

FIGS. 1A and 1B are graphic diagrams illustrating variations of threshold voltages of flash memory cells in accordance with program and erase operations.

Referring to FIG. 1A, by conducting a program operation, a threshold voltage of a flash memory cell increases from 1V through 3V to 6V through 8V. If the threshold voltage of the cell becomes higher, a drain current does not flow even when a read voltage is applied to the control gate. Such a condition is called as “programmed state” where data of “0” is stored in the flash memory cell.

Referring to FIG. 1B, by conducting a program operation, a threshold voltage of a flash memory cell decreases from 6V through 8V to 1V through 3V. With the lowered threshold voltage of the cell, a drain current flow therethrough when a read voltage is applied to the control gate. Such a condition is called as “erased state” where data of “1” is stored in the flash memory cell.

As stated above, the program operation is carried out to increase a threshold voltage of a cell, through which a predetermined drain current does not flow during a read operation. Therefore, if a threshold voltage of a cell is conditioned to be higher than a specific voltage, not to generate a drain current in the cell, there is no problem in a normal characteristic of the cell.

On the other hand, the erase operation is carried out to decrease a threshold voltage of a cell, through which a predetermined drain current flows during a read operation. However, although decreasing a threshold voltage of a cell, the erase operation must be confined to maintain the threshold voltage at a predetermined voltage level. In other words, if an erase operation progresses excessively to cause the threshold voltage under the predetermined voltage level (hereinafter, referred to as “over-erase”), it occurs a undesirable drain current nevertheless of applying a read voltage to the control gate and thereby causes an electrical error in its normal characteristic.

Hereinafter, it will be described about a procedure of generating a malfunction due to an over-erased cell with reference to FIG. 2.

Referring to FIG. 2, a bitline is generally connected to drains of plural flash memory cells C301˜C30n which are selected by address signals applied to wordlines WL301˜WL30n . Here, it will be assumed that a first flash memory cell C301 is in a programmed state, a second flash memory cell C302 has been over-erased, and a third flash memory cell C303 has been normally erased.

For example, in reading out data stored in the first flash memory cell C301, when a read voltage is applied to a control gate of the first flash memory cell C301, a drain current does not flow through the first flash memory cell C301 because a threshold voltage thereof is high by programming. Meanwhile, as the read voltage is not applied to the second and third flash memory cells, C302 and C303, drain currents, as a normal case, do not flow through the second and third flash memory cells C302 and C303. As a result, it will be normal that the amount of current detected on the bitline BL is 0A and the data stored in the first flash memory cell C301 is determined as “0”.

However, as assumed before, since the second flash memory C302 has been over-erased, a drain current I flows through the second flash memory cell C302 even without applying the read voltage thereto and thereby detected by way of the bitline BL. Thus, although the data stored in the first flash memory cell C301 is substantially “0”,it is erroneously detected to as “1” because of the drain current I flowing through the second flash memory cell C302 over-erased.

In order to solve such a problem, it is available to use a post-program operation to raise threshold voltages of over-erased cells up to a target voltage after performing an erase operation. But, even the post-program function does not assure of improving the reliability itself because there may be possibilities of remaining cells that have threshold voltages still not reaching the target voltage, which is insufficient to overcome the malfunctions. cl SUMMARY OF THE INVENTION

The present invention provides a method of erasing a flash memory cell that is a P-type well field-effective flash cell comprised of a drain formed in a P-type semiconductor substrate, a channel region made of a triple N-well, a source of P-well formed in the triple N-well, a floating gate formed on the channel region, a tunnel oxide film formed under the floating gate, and a control gate formed with a predetermined pattern on the overall structure including the floating gate. By the method, when the flash cell is turned on at a predetermined threshold voltage to drop a P-well bias, an electric field between the floating gate and the semiconductor substrate weakens to inhibit electron ejection that is caused by F-N tunneling effect and thereby an erased threshold voltage goes to a target voltage.

In the embodiment, a P-type well field-effective flash cell is comprised of a drain formed in a P-type semiconductor substrate, a channel region made of a triple N-well, a source of a P-well formed in the triple N-well, a floating gate formed on the channel region, a tunnel oxide film formed under the floating gate, a control gate formed with a predetermined pattern on the overall structure including the floating gate, and a dielectric film formed under the control gate.

In the structure, the edge of the floating gate is overlapped with the source and the drain.

On the other side, a wordline is connected to the control gate of the flash memory cell along the direction of the P-well, and connected to a wordline contact over the drain that is the P-type substrate.

In the embodiment, the tunnel oxide film is a field isolation film formed by a LOCOS process or a field isolation film constructed of a STI structure, and a thickness of the field isolation film is 200 nm through 300 nm.

In a method of erasing a flash memory cell, according to an embodiment of the present invention, a negative erasing voltage is applied to a control gate and a positive erasing voltage is applied to a P-well, so that charges accumulated in a floating gate of the flash memory cell described above are discharged from the floating gate.

In this embodiment, the negative erasing voltage may be −5V through −20V, while the positive erasing voltage may be 5V through 20V.

In this embodiment, it is preferable to apply a positive voltage to the triple N-well in order to retain the positive erasing voltage, which is applied to the P-well, in a P-N diode mode, during applying the erasing voltage. At this time, a voltage higher than a voltage applied to the P-well, by 0V through 5V, may be applied to the triple N-well.

### BRIEF DESCRIPTION OF THE DRAWINGS

FIGS. 1A and 1B are graphic diagrams illustrating variations of threshold voltages of flash memory cells in accordance with program and erase operations.

FIG. 2 is a circuit diagram illustrating a case of malfunction due to over-erased cells.

FIG. 3 is a layout diagram illustrating a P-type well field-effective flash cell in accordance with an exemplary embodiment of the present invention.

FIG. 4 is a cross-sectional diagram along the line A-A′ of FIG. 3.

FIG. 5 is a schematic diagram illustrating an operation of the P-type well field-effective flash cell in accordance with an embodiment of the present invention.

FIG. 6 is a graphic diagram illustrating the convergence of threshold voltages of the P-type well field-effective flash cell in accordance with the present invention.

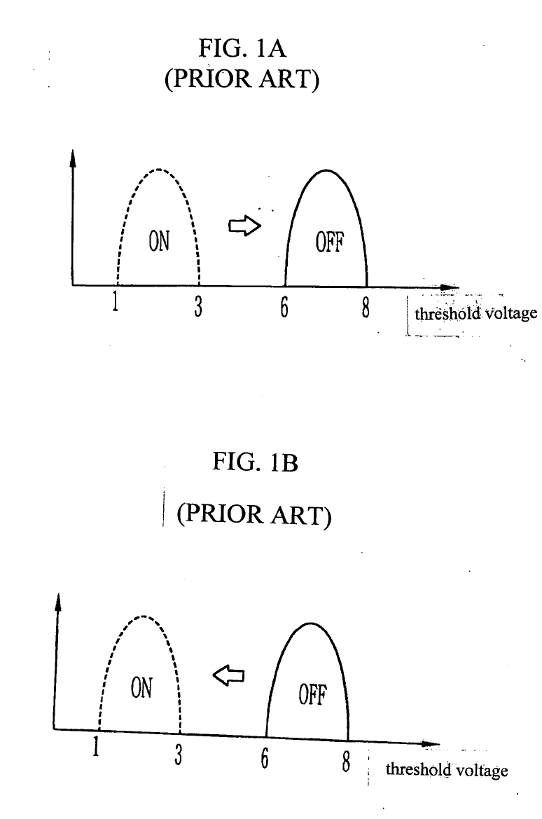

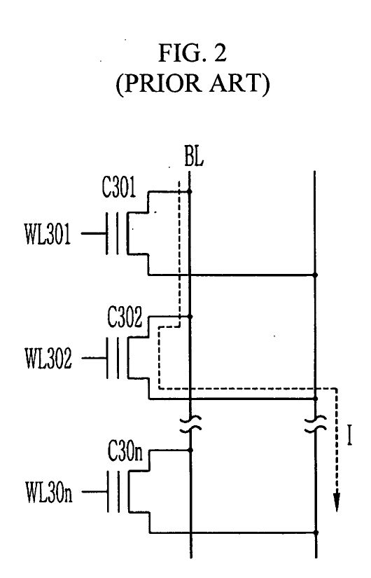

### DETAILED DESCRIPTION OF PREFERRED EMBODIMENTS

Now, preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the invention to those skilled in the art.

In this embodiment, the description that a film is formed “on” another film or a semiconductor substrate is preferred to be interpreted as it may be disposed with being directly contact to said another film or the substrate, or with interposing between them. In addition, the thicknesses or sizes of films or layers are illustrated a being magnified rather than their practical dimensions for clarification and understanding in convenience. Like numerals refer to like elements throughout the specification.

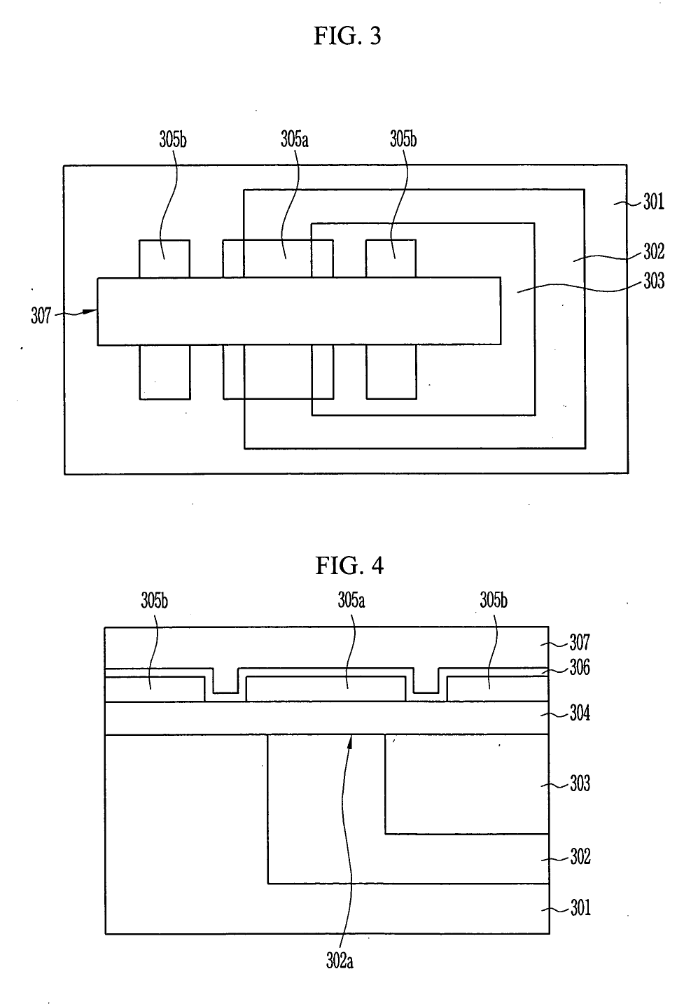

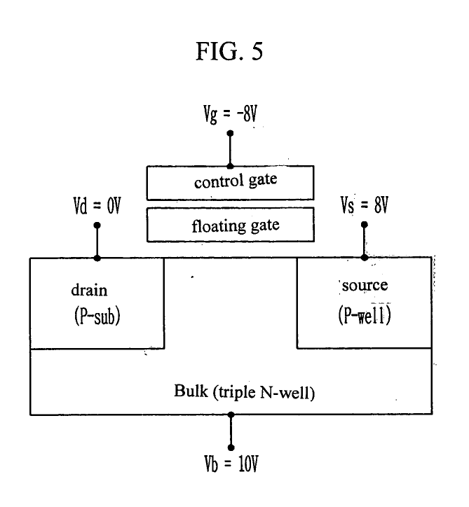

FIG. 3 is a layout diagram illustrating a P-type well field-effective flash cell in accordance with an exemplary embodiment of the present invention. FIG. 4 is a cross-sectional diagram along the line A-A′ of FIG. 3. FIG. 5 is a schematic diagram illustrating an operation of the P-type well field-effective flash cell in accordance with an embodiment of the present invention.

Referring to FIGS. 3 and 4, a P-type well field-effective flash cell according to the present invention is comprised of a drain 301 formed in a P-type semiconductor substrate 301, a channel region 302a made of a triple N-well 302, a source 303 of a P-well 303 formed in the triple N-well 302, a floating gate 305a formed on the channel region 302, a tunnel oxide 304 film formed under the floating gate 305a, a control gate 307 formed with a predetermined pattern on the overall structure including the floating gate 305a, and a dielectric film 306 formed under the control gate 307.

In the structure, the edge of the floating gate 305a can be overlapped with the drain 301 and the source 303.

On the other side, a wordline is connected to the control gate of the flash memory cell along the direction of the P-well, and connected to a wordline contact over the drain that is the P-type substrate.

The tunnel oxide film 304 may be usable with a field isolation film formed by a LOCOS process or constructed of an STI structure, preferably being with the thickness of 200 nm through 300 nm.

The control gate 307 is formed with being extended over the P-type substrate 301 and the P-well 303.

With the structure of the P-type well field-effective flash cell, a method of erasing the cell is as follows.

The P-type well field-effective flash cell as shown the aforementioned structure is designed to have a gate coupling ratio about 0.9. In a channel erase method for an N-type NOR flash device, when a negative voltage of −5V through −20V (preferably, −8V) is applied to the control gate 307 and a positive voltage of 5V through 20V (preferably, 8V) is applied to the P-well 303, an electric field is generated to cause an erase operation by discharging electrons from the floating gate 305a into the channel region 302a through the F-N tunneling effect. The p-type well field-effective flash cell according to the present invention also accords as contemporaneous as the mechanism.

During this, in order to retain a voltage, which is applied to the P-well 303, in a P-N diode mode, it is desirable to apply a voltage, higher than the voltage applied to the P-well, to the triple N-well 302 belonging to the channel region 302a. Then, it is possible to adjust a voltage applied to the triple N-well 302 by using the facts that a potential lowered by the gate coupling ratio is induced at the floating gate 305a and a Gamma value is high due to the thick tunnel oxide film 304. In other words, a threshold voltage is adjustable by means of a back-gate bias effect. When a threshold voltage reaches a target voltage, the P-type well field-effective flash cell is turned on to cause a current flow toward the P-type substrate 301 of the drain from the P-well 303 of the source, which decreases the electric field around the tunnel oxide film 304 of the flash cell. As a result, the amount of electrons emitted from the floating gate 305a reduces exponentially, so that the threshold voltage of the flash cell converges on the target voltage.

Accordingly, it is possible to prevent the over-erasure from being generated.

As another way of operating a threshold voltage of the P-type well field-effective flash cell to be approached to a target voltage, it is available to increase the threshold voltage in the mechanism of hot carrier injection by enhancing the current drivability of the P-well.

Otherwise, it is also possible to adjust the threshold voltage by modifying a channel width or by variably designing the triple N-well that establishes a channel length.

FIG. 5 is a schematic diagram illustrating an operation of the P-type well field-effective flash cell in accordance with an embodiment of the present invention, as comparative to a normal cell structure.

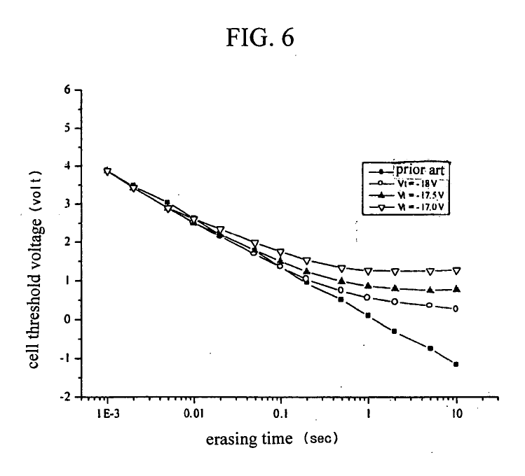

FIG. 6 is a graphic diagram illustrating the convergence of threshold voltages of the P-type well field-effective flash cell in accordance with the present invention.

Referring to FIG. 6, in the conventional case, as an erasing time becomes longer, threshold voltages of cells is continuously lowered to result in the over-erasure. By the contrary, in the present invention, it can be seen that threshold voltages of cells do not drop under the target voltage (e.g., 0.3V through 1.4V) and converge on the target voltage, even though an erasing time becomes longer, so that the over-erasure does not occur therein.

As described above, the present invention prevents an over-erasure by controlling threshold voltage of erased cells to converge on a predetermined target voltage, resulting in protection of recovery defects, reduction of recovery times, and improvements of electrical characteristics of device, enhancing the reliability of circuit thereof as well.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A flash memory cell comprising:
a drain formed in a P-type semiconductor substrate;
a channel region made of a triple N-well;
a source of a P-well formed in the triple N-well;
a floating gate formed on the channel region;
a tunnel oxide film formed under the floating gate;
a control gate formed with a predetermined pattern on the overall structure including the floating gate; and
a dielectric film formed under the control gate.

2. The flash memory cell as set forth in claim 1, wherein an edge of the floating gate is overlapped with the source and the drain.

3. The flash memory cell as set forth in claim 1, further comprising a poly-silicon layer interposed between the tunnel oxide film and the dielectric film over the P-well.

4. The flash memory cell as set forth in claim 1, further comprising a poly-silicon layer interposed between the tunnel oxide film and the dielectric film over the drain.

5. The flash memory cell as set forth in claim 1, wherein the tunnel oxide film is a field isolation film formed by a LOCOS process or a field isolation film constructed of a STI structure.

6. The flash memory cell as set forth in claim 5, wherein a thickness of the field isolation film is 200 nm through 300 nm.

7. A method of erasing a flash memory cell, comprising:
applying a negative erasing voltage to a control gate; and
applying a positive erasing voltage to a P-well;
whereby charges accumulated in a floating gate of a flash memory cell described in claim 1 are discharged from the floating gate.

8. The method as set forth in claim 7, wherein the negative erasing voltage is −5V through −20V.

9. The method as set forth in claim 7, wherein the positive erasing voltage is 5V through 20V.

10. The method as set forth in claim 7, wherein a positive voltage is applied to the triple N-well to retain the positive erasing voltage, which is applied to the P-well, in a P-N diode mode, during applying the erasing voltage.

11. The method as set forth in claim 10, wherein a voltage higher than a voltage applied to the P-well is applied to the triple N-well.

12. The method as set forth in claim 11, wherein a voltage higher than a voltage applied to the P-well, by 0V through 5V, is applied to the triple N-well.
